(19) United States
(12) Patent Application Publication
(10) Pub. No.: US 2017/0160324 A1
(43) Pub. Date: Jun. 8, 2017

(54) PROBE ASSEMBLY FOR PERFORMING ELECTROMAGNETIC FIELD MAPPING AROUND AN ANTENNA

(71) Applicant: HALLIBURTON ENERGY SERVICES, INC., Houston, TX (US)

(72) Inventors: Jesse Kevin Hensarling, Cleveland, TX (US); Matthew Chase Griffing, Kingwood, TX (US)

(73) Assignee: HALLIBURTON ENERGY SERVICES, INC., Houston, TX (US)

(21) Appl. No.: 14/766,972

(22) PCT Filed: Jul. 29, 2015
(86) PCT No.: PCT/US2015/042612

§ 371 Date: Aug. 10, 2015

Related U.S. Application Data
(60) Provisional application No. 62/039,124, filed on Aug. 19, 2014.
(60) Provisional application No. 62/035,939, filed on Aug. 11, 2014.

(51) Int. Cl. G01R 29/10; G01V 3/28

(52) U.S. Cl. CPC G01R 29/10; G01V 3/28

(57) ABSTRACT

A probe assembly for performing electromagnetic (EM) field mapping around an antenna, the probe assembly comprising a probe head base and three coils wrapped around the base and oriented in different directions. An EM field mapping apparatus to acquire multicomponent EM field measurements comprised of a non-metallic/non-magnetic frame, a set of linear motion actuators, a probe, a sensor, and a controller. An EM logging method that comprises constructing an EM logging tool having one or more antennas, mapping an EM field pattern for each of the one or more antennas, deriving an EM logging tool model, obtaining measurements using the EM logging tool, and inverting/transforming the measurements using the EM logging tool model to obtain the estimated formation.

### CROSS REFERENCE TO RELATED APPLICATIONS

The present application claims priority to U.S. Provisional Pat. App. 62/039,124, titled “Probe Assembly for Performing Electromagnetic Field Mapping Around an Antenna”, and filed Aug. 19, 2014 by Jesse Hensarling et al. The present application also claims priority to U.S. Provisional Pat. App. 62/035,939, titled “Probe Assembly for Performing Electromagnetic Field Mapping Around an Antenna”, and filed Aug. 11, 2014 by Jesse Hensarling et al. The above-noted priority applications are hereby incorporated herein by reference in their entirety.

### BACKGROUND

This disclosure is related to systems and methods for characterizing fields of electromagnetic (EM) antennas like those that may be found in “logging while drilling” (LWD) tools. Well drilling operators often use downhole data to determine present downhole conditions or to adjust drilling plans as needed. One method of gathering downhole data is to deploy one or more antennas as part of a bottom hole assembly (BHA). Such antennas are typically wrapped around the exterior of a drill pipe or collar to emit or receive EM energy. EM analysis using BHA antennas can provide valuable information regarding the formation characteristics (e.g., resistivity, porosity, density, presence of fluids, boundary detection, geo steering, etc.).

EM analysis is often based on assumptions of idealized radiation and sensitivity field patterns, yet the actual field patterns are impacted by physical limitations in the antenna manufacturing process, the proximity of metal and electronic devices on/near the BHA, or other unpredictable variables; even elaborate EM modeling software may not predict all the unknown effects. Therefore, an antenna's EM field needs to be measured or “mapped”. Such mapping can be performed before deploying an antenna downhole using a small probe that is physically moved around the antenna to detect the strength of the magnetic field around the antenna relative to one or more test currents or measured voltages. One of the difficulties in performing EM field mapping for an antenna is related to the limitations of the probe used. Typical probes used in the industry are capable of only 1-dimensional (1D) or 2-dimensional (2D) EM field sensing, and in some instances are only intended for field detection and not calibrated measurement (e.g., EMI sniffer probes). Another limitation of existing probes (including 3D probes) is that their large size inhibits movement around the antenna being tested and the resolution of the field measurement.

### BRIEF DESCRIPTION OF THE DRAWINGS

Accordingly, there are disclosed in the drawings and the following description a probe for electromagnetic (EM) field mapping intended to address the above-mentioned limitations. In the drawings:

FIGS. 1a and 1b are schematic diagrams showing typical drilling environments.

FIGS. 2a and 2b are schematic diagrams showing different antenna configurations.

FIG. 3 is a perspective view of an illustrative probe assembly.

FIG. 4 is a perspective view of an illustrative probe stem.

FIG. 5 is a perspective view of an illustrative probe tip.

FIGS. 6a, 6b, and 6c are perspective views of an illustrative three-axis probe head.

FIGS. 7a and 7b are perspective views of an illustrative electrostatic shield assembly.

FIG. 8a is a schematic diagram of an illustrative tuned pickup coil circuit.

FIG. 8b is a graph showing illustrative frequency responses of L and LC circuits.

FIG. 9 is a schematic view of an illustrative probe sensitivity test or calibration arrangement.

FIG. 10 is a schematic view of an illustrative three-dimensional (3D) electromagnetic (EM) field mapping system.

FIG. 11 is a schematic view showing a two-dimensional (2D) slice of an illustrative EM field pattern for a tilted coil antenna.

FIG. 12 is a block diagram of a method of performing EM field mapping of an antenna.

FIG. 13 is a block diagram of performing an EM logging method.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### NOMENCLATURE

Certain terms are used throughout the following description and claims to refer to particular system components. This document does not intend to distinguish between components that differ in name but not function. The terms “including” and “comprising” are used in an open-ended fashion, and thus should be interpreted to mean “including, but not limited to . . . ”. The term “couple” or “couples” is intended to mean either an indirect or direct electrical, mechanical, or thermal connection. Thus, if a first device couples to a second device, that connection may be through a direct connection, or through an indirect connection via other devices and connections. Conversely, the term “connected” when unqualified should be interpreted to mean a direct connection. For an electrical connection, this term means that two elements are attached via an electrical path having essentially zero impedance.

### DETAILED DESCRIPTION

Disclosed herein is a three-axis probe and related methods and systems for performing three-dimensional (3D) electromagnetic (EM) field mapping operations. The probe may be, for example, one component of a test stand assembly or actuation system designed to map the output EM field of an antenna in a lab environment. Since EM fields are affected by metallic objects, the test stand may be constructed of non-metallic, non-magnetic, or non-ferrous materials. Likewise, probe assembly structural components may be non-metallic with the exception of the pickup coils, which are made of lengths of metal wire. In at least some embodiments, the test stand is able to move the probe assembly in three dimensions relative to the antenna. Additionally or alternatively, the test stand may be designed to move the antenna relative to the probe (e.g., rotating the antenna).

Once an antenna's EM field is mapped, downhole EM analysis based on the antenna can be tuned or calibrated to improve the accuracy of formation characteristics or other information to be derived from EM signals collected using the antenna. One or more “mapped” antennas may be included with an EM logging tool deployed using a drill string (e.g., a logging-while-drilling (LWD) tool included with a bottom hole assembly (BHA)), a wireline, or coiled tubing.

Without limitation, antennas for EM logging operations are sized to fit into a borehole. As a result, such antennas typically are 10 inches or less in diameter. Common logging tool diameter sizes include 9.5, 8, 6.75, 4.75, 3.625, and 3.125 inches. The measurable EM field propagation depth, or Depth of Investigation (DOI), in a formation is approximately 0-30 meters (up to 100 ft.), depending on the frequency of the EM field emitted and the physical spacing between the transmitter and receiver antennas along the length of the drill collar.

An example system is a probe assembly for performing electromagnetic (EM) field mapping around an antenna, the probe assembly comprising a probe head base and three coils wrapped around the probe head base and oriented in different directions and orthogonal to each other.

In at least some embodiments, a three-axis probe includes three orthogonally-oriented coils, where the size of each coil is small (less than 1 inch). However, it should be appreciated that such probes may be manufactured in a range of sizes to accommodate a wide range of antenna styles and shapes, depending on the application. Regardless of size, the packaging for the probe coils is preferably non-metallic. Further, the test stand for each probe is capable of moving the probe or test antenna relative to each other in three independent dimensions. Further, each probe may be configurable to accommodate a wide range of power levels and frequency ranges being tested. For example, adding a capacitance for each probe coil results in a tunable inductor-capacitor (LC) circuit. Each LC circuit can be “tuned” to be sensitive to a particular frequency range and less sensitive to other frequencies.

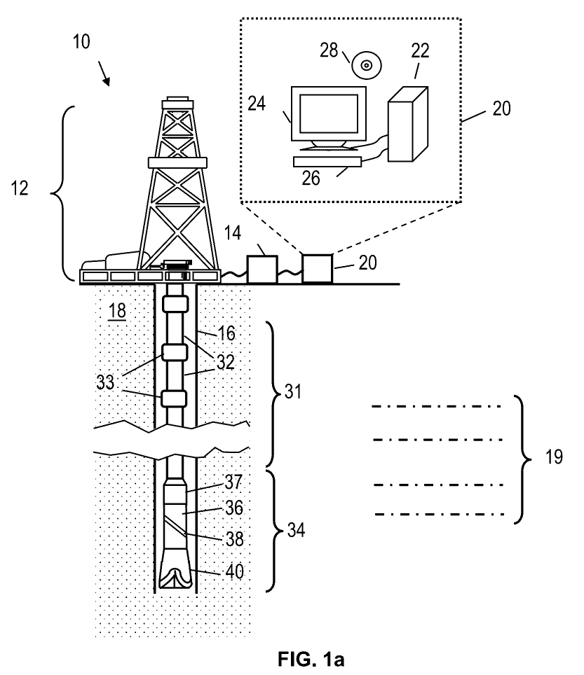

The present disclosure is best understood by viewing an EM logging environment. Accordingly, FIG. 1a shows an illustrative drilling environment 10, where a drilling assembly 12 enables a drill string 31 to be lowered and raised in a borehole 16 that penetrates formation 19 of the earth 18. The drill string 31 is formed, for example, from a modular set of drill pipe sections 32 and adaptors 33. At the lower end of the drill string 31, a bottom hole assembly (BHA) 34 with a drill bit 40 removes material from the formation 19 using known drilling techniques. The BHA 34 also includes one or more drill collars 37 and may include an EM logging tool 36 to collect EM data using one or more mapped antennas 38.

In FIG. 1a, an interface 14 at earth's surface receives EM logging data collected by the EM logging tool 36 via mud-based telemetry or other wireless communication techniques (e.g., electromagnetic or acoustic). Additionally or alternatively, a cable including electrical conductors or optical waveguides (e.g., fibers) may be used to enable transfer of power or communications between the BHA 34 and the earth's surface. Such cables may be integrated with, attached to, or inside components of the drill string 31 (e.g., sections of wired drill pipe may be used).

The interface 14 may perform various operations such as converting signals from one format to another, filtering, demodulation, digitization, or other operations. Further, the interface 14 conveys the EM measurements or related data to a computer system 20 for storage, visualization, or analysis. In at least some embodiments, the computer system 20 includes a processing unit 22 that enables visualization or analysis of EM logging data by executing software or instructions obtained from a local or remote non-transitory computer-readable medium 28. The computer system 20 also may include an input device(s) 26 (e.g., a keyboard, mouse, touchpad, etc.) and output device(s) 24 (e.g., a monitor, printer, etc.). Such input device(s) 26 or output device(s) 24 provide a user interface that enables an operator to interact with the EM logging tool 36 or software executed by the processing unit 22. For example, the computer system 20 may enable an operator to select EM logging options, to select visualization or EM analysis options, to adjust drilling options, or to perform other tasks.

At various times during the drilling process, the drill string 31 shown in FIG. 1a may be removed from the borehole 16. With the drill string 31 removed, wireline logging operations may be performed as shown in the wireline logging survey environment of FIG. 1b. In FIG. 1b, a wireline logging string 56 is suspended in borehole 16 that penetrates formation 19 of the earth 18. For example, the wireline logging string 56 may be suspended by a cable 15 having conductors or optical fibers for conveying power to the wireline logging string 56. The cable 15 may also be used as a communication interface for uphole or downhole communications. For example, the cable 15 may be used to activate a sensor 39 or otherwise enable uphole transmissions of field measurements collected by the antenna 38. In at least some embodiments, the cable 15 wraps and unwraps as needed around cable reel 54 when lowering or raising the wireline logging string 56. As shown, the cable reel 54 may be part of a movable logging facility or vehicle 51 having a cable guide 52.

The wireline logging string 56 includes logging tool body 59, a logging tool 58, the sensor(s) 39, and the antenna 38. The antenna 38 may be energized and controlled by either a power source on the logging tool 58 or at the surface. The antenna 38 generates an EM field for analysis of the nearby formation 19 and sends data either back to the logging tool 58 or the surface equipment. The logging tool 58 may also include electronics for data storage, communication, etc. The measurements obtained by sensor(s) 39 are conveyed to earth's surface or are stored by the logging tool 58. As previously noted, such measurements as a function of position or time may be analyzed to determine formation properties, fluid properties, or fluid flow properties as described herein. At earth's surface, the interface 14 receives the measurements via the cable 15 or other telemetry, and conveys the measurements to the computer system 20, or another computer system, for analysis.

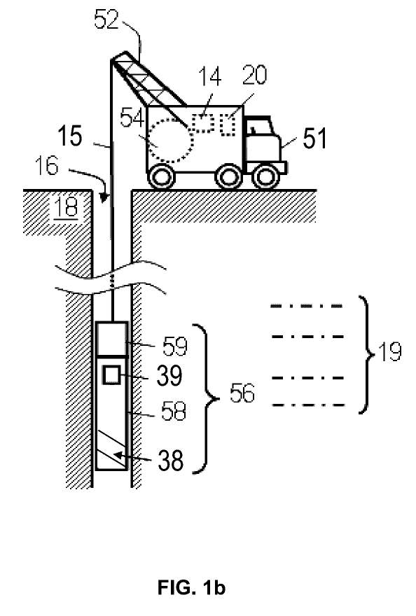

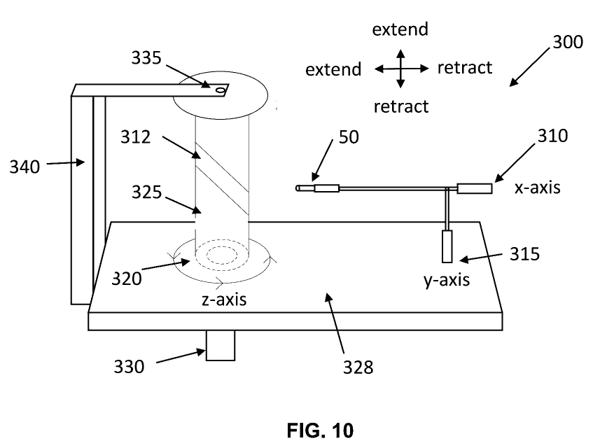

In FIG. 2a, the mapped antenna 38 is shown with a co-axial orientation relative to the EM logging tool 36. In FIG. 2b, the mapped antenna 38 is shown with an angled (tilted) orientation relative to the EM logging tool 36. FIGS. 2a & 2b may also represent an antenna test configuration, where an antenna under test 312 is positioned around a tool body 325 (see FIG. 10). Without limitation, the mapped antenna 38 represented in FIG. 2b may be at an angle of approximately 45° relative to the longitudinal axis of the EM logging tool 36. In an example co-axial or tilted antenna application, the mapped antenna 38 operates using a sinusoidal signal between the ranges of 10 Hz-10 MHz to obtain information regarding formation 19 within a range of 0-30 meters or more.

While the EM logging tool 36 has been described for a drilling environment, it should be appreciated that wireline or coiled tubing logging operations may also employ EM logging tools with co-axial or tilted antenna configurations. Regardless of the particular logging environment, EM analysis of EM logging data can be tuned or calibrated based on the mapped antenna (e.g., antenna 38), where the EM field mapping is obtained using a disclosed three-axis probe assembly and a test stand 328 assembly.

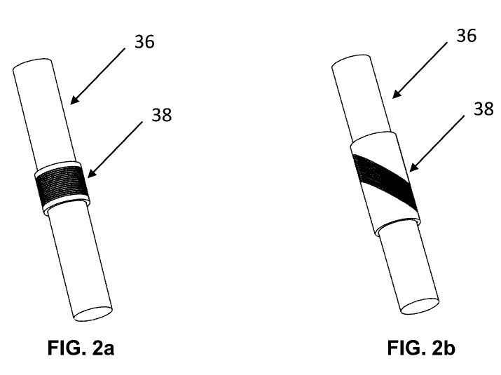

FIG. 3 shows a three-axis probe assembly 50. The probe assembly 50 includes a modular head assembly 55, a tip assembly 100, and a probe stem assembly 200. The different components of the probe assembly 50 may be temporarily or permanently attached to each other using mechanical connectors (e.g., friction fitted parts, threaded connectors, mated parts, etc.), adhesives, or other known connection techniques. As shown in FIG. 3, the probe assembly also includes wires 70, 72, and 74 corresponding to three coils that reside in the head assembly 55. The wires extend from the head assembly 55 and pass through the tip assembly 100 and the probe stem assembly 200 with a length sufficient to allow connection to a network analyzer, spectrum analyzer, oscilloscope, or other test equipment (not shown). Each of the wires 70, 72, and 74 has a corresponding wire termination 75. The exact configuration of the wire terminations 75 depends on the test setup and frequency range under test. In one embodiment, the wire terminations 75 are simply bare wire. In other embodiments, the wire terminations 75 may include, but are not limited to, mechanical connectors, terminals, coaxial connectors, or RF connectors. Except for the wires 70, 72, and 74 (and related coils), the probe assembly 50 is preferably constructed from non-metallic or non-magnetic materials such as wood, ceramic, glass, polymers including Kevlar, nylon, and Teflon, resin, or composite materials including fiberglass. However, in alternative embodiments, at least some parts of the probe assembly 50 (e.g., some or all of the head assembly 55, some or all of the tip assembly 100, or some or all of the probe stem assembly 200) may be constructed with magnetic or metallic materials to enhance or “tune” the performance of the probe assembly 50. In at least some embodiments, the probe assembly 50 also includes an electrostatic or electric field shield assembly (“shield”) 135. The shield 135 is designed to shield the head assembly 55 from unwanted electric fields and associated “stray” voltages. For example, unwanted electric fields may originate from nearby electrical devices including computers, power supplies, ambient static electricity, nearby test equipment, and even the voltage potential between the antenna and the probe coils. The shield 135 operates by electrically collecting stray voltages picked up by the probe assembly 50 and shunting the resultant energy to an electrostatic or electric field ground (or drain) wire 140. The shield 135 is designed to slip over the head assembly 55 and tip assembly 100 and remains in place using, for example, a friction fit, threaded connectors, mated parts, or other attachment mechanisms that allow a test operator to quickly attach or remove the shield 135 without the use of tools.

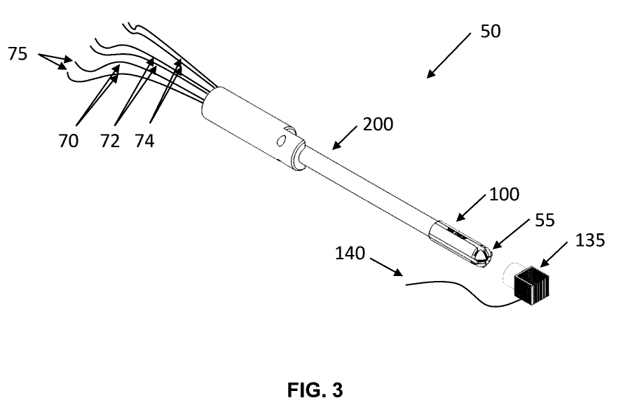

FIG. 4 shows the probe stem assembly 200. The probe stem assembly 200 is designed to securely hold the tip assembly 100 and to be fixably attached to a 3D actuation system (e.g., an actuation system 300 of FIG. 10). The probe stem assembly 200 includes a stem socket 205, a stem body 210, a stem anterior end 220, a stem posterior end 225, and a hollow stem region 215 extending through the probe stem assembly 200 to allow the wires 70, 72, 74 to pass through from the stem posterior end 225 to the stem anterior end 220.

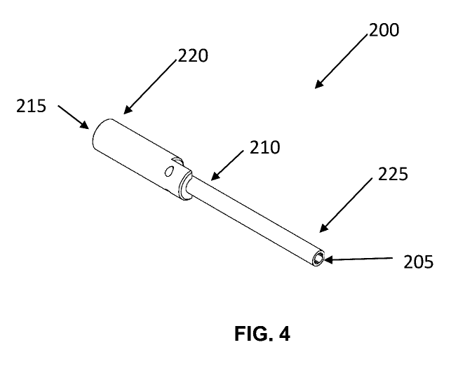

In at least some embodiments, the stem anterior end 220 is designed to interface with x-axis and y-axis linear actuators 310, 315 of the actuation system 300 (see FIG. 10). As such, the stem anterior end 220 may take on a variety of forms and attachment styles according to the design of the associated actuation equipment. In one embodiment, the stem body 210 is held in place using a friction fit mechanical attachment method. In another embodiment, the stem body 210 can be held in place using attachment methods including, but not limited to, adhesives, clamps, or tie-wraps, and non-metallic/non-magnetic bolts or screws. Meanwhile, the stem socket 205 may employ a socket end to accommodate the tip assembly 100 via a tip plug 115 (see FIG. 5). By running the wires 70, 72, 74 through the probe stem assembly 200, protection is provided as the actuation system 300 (see FIG. 10) moves during EM field mapping operations. The probe stem assembly 200 performs another function by helping to isolate the head assembly 55 physically apart from the bulk of the actuation system 300. By necessity, components of the actuation system 300 include both metallic objects and devices emanating unwanted electromagnetic fields. As needed, a test operator can vary the length of the probe stem assembly 200 to improve performance of the probe assembly 50 by moving it further away from unwanted noise sources.

FIG. 5 shows the tip assembly 100. The tip assembly 100 includes a tip body 105, a set of at least two tip tines 110 for mechanically locking the head assembly 55 into position, the tip plug 115 to facilitate attachment to the probe stem assembly 200, a tip socket 125, and a hollow center region 120 to allow the wires 70, 72, 74 from the head assembly 55 to pass through the tip socket 125 and the tip plug 115. The tip plug 115 attaches to the probe stem assembly 200, for example, using a friction fit with the stem socket 205, but other mechanical attachment options are possible.

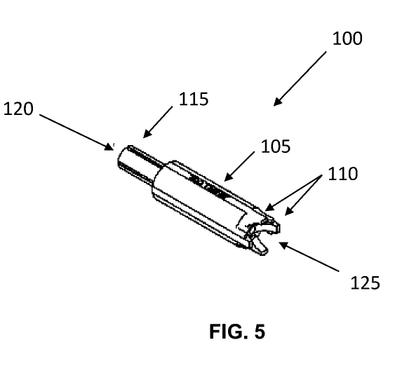

FIGS. 6a, 6b, and 6c show the head assembly 55. The head assembly 55 is comprised of a head base 60 and three coils corresponding to wires 70, 72, and 74. For convenience, the three coils are orthogonally-oriented relative to the x, y, and z-axes shown for FIGS. 6a and 6b. The wires 70, 72, and 74 may correspond to insulated copper wire. In other embodiments, the wires 70, 72, 74 may correspond to twisted pair wire, coaxial cable, and other forms of impedance-matched conductors. The head assembly 55 is constructed by winding different wires 70, 72, 74 into different tracks 62, 64, 66 of the head base 60 for a predetermined number of turns. Additionally, a length of each wire 70, 72, 74 is left unwound and passes through the tip assembly 100 and probe stem assembly 200 for connection with test equipment including, but not limited to, a network analyzer, spectrum analyzer, or an oscilloscope.

In at least some embodiments, the length of each wire 70, 72, 74 is calculated from a derivation of the Faraday Law equation with the resultant head assembly 55 having a particular sensitivity due to the length of wire 70, 72, 74 used. The desired sensitivity for a given coil axis can be calculated and resultant wire length determined from the following sensitivity equation for an-untuned pickup coil in the direction of that axis:

Sensitivity(Volts/Tesla)=V/B=2πf NA (Equation 1)

where flux density B=μₒH, H is the magnetic field in A/m, μₒ is the permeability of free space (4π×10−7 H/m), f is the frequency in Hz, N is the number of turns, A is the loop area in square meters, and NA=loop effective aperture (Aₑ).

The diameter of the head base 60 ultimately determines both the measurement resolution and the physical size (diameter) of the probe tip assembly 100, while the diameter/thickness of the probe stem assembly 200 depends more on the length and weight the probe stem assembly 200 has to support without significant droop/deflection. The probe stem assembly 200 must also be sufficiently large to receive and support the tip assembly 100. As an example, the head base 60 with a diameter of 0.25 inches may correspond to a measurement resolution of approximately 0.25 inches. For this example, overall diameter of the probe stem assembly 200 may be approximately 0.5 inches and the overall length of the probe assembly may be approximately 18 inches. As another example, the head base 60 with a diameter of 1 inch corresponds to a resolution of approximately 1 inch. In such case, the overall width of the probe stem assembly 200 is approximately 1½ inches and the overall length of the probe assembly is approximately 48 inches. In at least some embodiments, the head base 60 with a diameter of ¼ to ½ inch is used. For each of the coils corresponding to wires 70, 72, 74, EM field values and measurement variables r, L, and θ (described later) may be tracked to create an EM field map, where r is the radial distance from the center of the antenna being tested, L is the height of the probe assembly 50 relative to the antenna being tested, and θ is the rotation angle of the antenna being tested around a central axis.

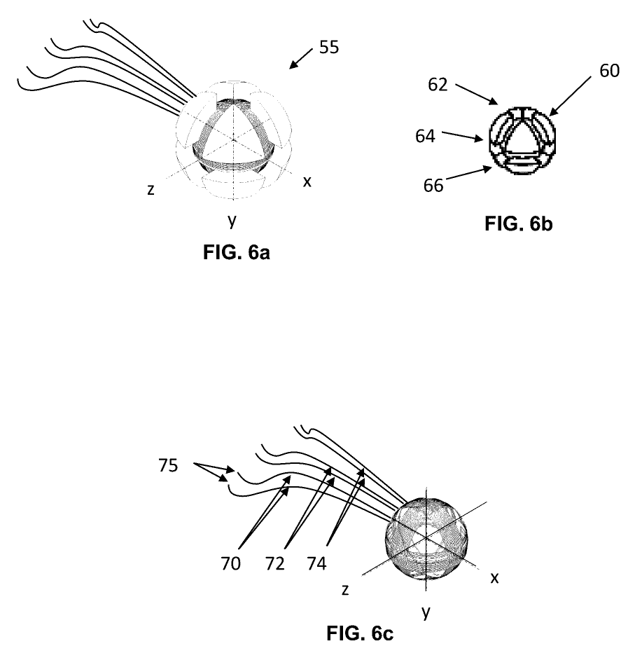

FIG. 7a displays a conductive grid 138 used for the electrostatic (electric field) shield assembly 135, where the conductive grid 138 is shown in an unfolded state. The conductive grid 138 is comprised of an array of conducting wires or traces or, alternatively, a mesh of conducting material on an insulating substrate. The conductive grid 138 may be manufactured as a flat sheet and folded to create an open-ended cube shape used for the electrostatic shield assembly 135. FIG. 7b shows the complete electrostatic shield assembly 135 with the folded conductive grid 138 fixably attached to a shield body/form 137 and the ground (drain) wire 140 electrically connected to the conductive grid 138, the ground wire 140 electrically connected to each conductor of the conductive grid 138 at only a single point, such that no current will flow to interfere with the magnetic field with the other end of the ground wire 140 electrically connected to the reference potential of the instrumentation that the probe assembly 50 is interfaced to (e.g., the network analyzer, spectrum analyzer, or oscilloscope). The shield body/form 137 is constructed so as to fit around the tip assembly 100 and surround the head assembly 55 thus allowing the conductive grid 138 to surround the head assembly 55 with a metallic structure that permits passage of magnetic fields while blocking electrical currents and fields and shunting capacitively-coupled electrical energy away to ground via the ground wire 140. The shield body/form 137 may be constructed of metallic or non-metallic materials as appropriate.

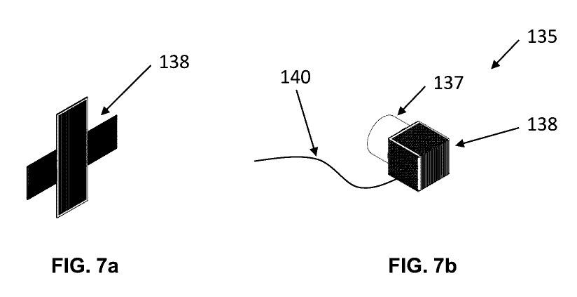

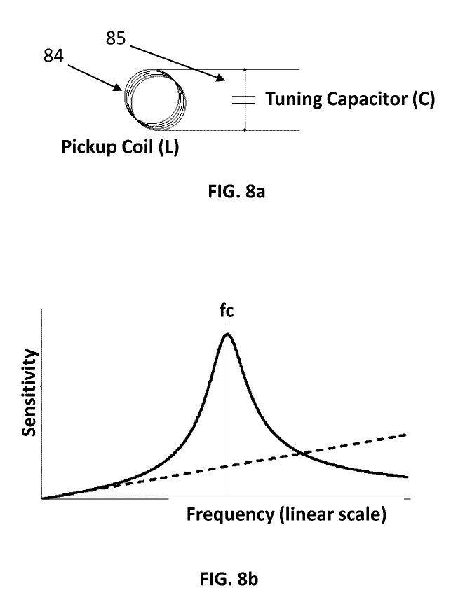

FIG. 8a shows a schematic diagram of an LC circuit with a coil 84 and a tuning capacitor 85 in parallel with the coil 84. The coil 84 may correspond to, for example, any of the coils related to wires 70, 72, and 74 (each wire 70, 72, 74 is wound around the head base 60, creating an inductor). By placing the capacitor 85 across the coil for each wire 70, 72, and 74, an LC circuit is created.

As seen in the graph shown in FIG. 8b, a simple or “untuned” inductor circuit's sensitivity increases linearly with an increase in operating frequency. The graph displays the sensitivity of an untuned coil as a dashed line and the sensitivity of a tuned coil as a solid line. FIG. 8b shows the maximum sensitivity at the center frequency (f_{c}) for an LC circuit and reduced sensitivity as the distance from the center frequency increases. Additionally, FIG. 8b shows that the sensitivity of the LC circuit is unchanged compared to the inductor (L) circuit at lower frequencies and has a lower sensitivity than the inductor (L) circuit at higher frequencies beyond the center frequency f due to the low impedance of the capacitor at high frequencies shunting the signal. Accordingly, the probe assembly 50 having the coil 84 and the capacitor 85 can be constructed to be sensitive to particular center frequencies as desired. More specifically, each winding of the wires 70, 72, and 74 can be individually tuned for a customized sensitivity range by varying the length of wires 70, 72, and 74 to adjust inductance/sensitivity by varying the number of turns or by adding the capacitor 85 in parallel with each corresponding coil. The sensitivity for a tuned pickup coil in the direction of a given coil axis can be calculated from the following equation:

$$Sensitivity ( \frac{Volts}{Tesla} ) = \frac{V}{B} = \frac{- j 2 π fNA}{( 1 - {LC ( 2 π f )}^{2} ) + jRC ( 2 π f )} \qquad Equation ( 2 )$$

where L is the inductance of pickup coil, C is the tuning capacitance, and R is the series resistance of the pickup coil. The center frequency (f_{c}) is given approximately by:

$${f}_{c} ( Hz ) = \frac{1}{2 π \sqrt{LC}} .$$

The 3 dB Bandwidth (BW) is given by:

$$BW ( Hz ) = \frac{fc}{Q} , where Q = \frac{1}{2 π fcRC} or , alternatively Q = \frac{2 π fcL}{R} \qquad Equation ( 3 )$$

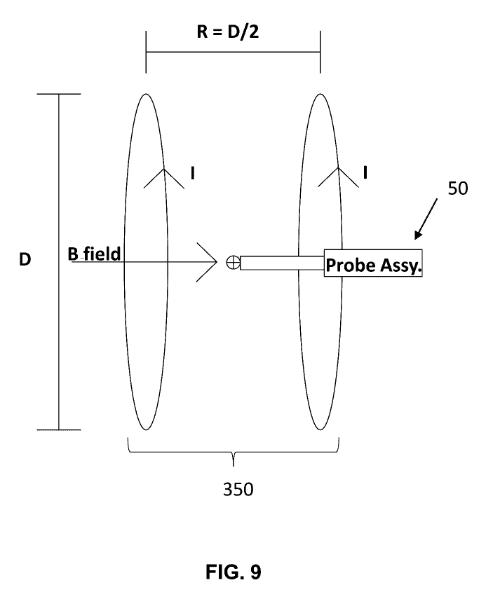

FIG. 9 shows a test setup for determining sensitivity of the probe assembly 50 using a Helmholtz Coil 350. The Helmholtz Coil 350 comprises of a pair of identical windings placed in parallel association with each other which, when energized, produces a nearly uniform magnetic field between the windings. With the test setup of FIG. 9, a probe assembly's sensitivity to a known magnetic field can be measured accurately. The advantage of using the Helmholtz Coil 350 is that one practically sized for the laboratory produces a large uniform field compared to the size/resolution of the head assembly 55 (of FIG. 6a) such that the location of a probe in the magnetic field under test is not critical and need not be precise. Once the sensitivity of the probe assembly 50 to a known magnetic field has been determined, decisions can be made regarding how to perform EM field mapping operations for a test antenna as described herein. For example, at least the excitation power or frequency of the antenna under test 312 (of FIG. 10) can be determined based on a predetermined sensitivity of the probe assembly 50.

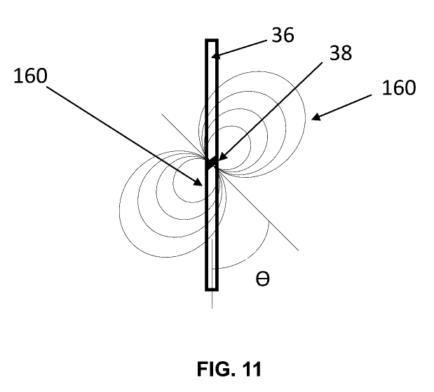

FIG. 10 shows the actuation system 300 comprising the test stand 328, the set of two linear actuators 310, 315 (for (x-axis) extend/retract movements as well as (y-axis) extend/retract movements of probe assembly 50) (said x- and y-axis designations arbitrarily designated and may be assigned a different label), a rotating table 320 (for rotation of the antenna under test 312), and the tool body 325 (e.g., an EM logging tool body). When possible, EM logging tool components and EM field mapping components are constructed of non-metallic or non-magnetic structural materials such as wood, ceramic, glass, polymers including Kevlar, nylon, and Teflon, resin, or composite materials including fiberglass. In this way, distortions to a test antenna's electromagnetic field 160 (see FIG. 11) are minimized. It should be noted that it might be technically difficult to construct the actuation system 300 wholly without metal, but in many cases the non-metallic struts or other such components may be employed to distance any necessary metal components from the sensing region. Specifically, at least the motors and linear motion actuators may include metal components.

In at least some embodiments, performing EM field mapping for the antenna under test 312 includes using the test stand 328, placing the antenna under test 312 around the tool body 325, and placing the tool body 325 onto the rotating table 320. The antenna under test 312 is mechanically held in place on the rotating table 320 with the use of a rotation pivot point 335, fixed into place by use of a test stand arm 340. The use of the test stand arm 340 in association with the pivot point 335 provides additional structural support for the antenna under test 312 and provides a secure, safe, and more accurate test environment. The rotating table 320 can be rotated by, but is not limited to, manual rotation by an operator or using a stepper motor 330 to rotate the tool body 325 containing the antenna under test 312 in controlled discrete increments as measured in distance, radians, or degrees moved. In an alternative embodiment, the stepper motor 330 may also be located and mounted to the test stand 328 at a distance from the rotating table 320 to isolate the stepper motor 330 it from the magnetic fields near the antenna under test 312. In this embodiment, the stepper motor 330 may drive the rotating table 320 by employment of a flexible non-metallic belt, driveshaft, or gears.

Continuing with FIG. 10, as the antenna under test 312 emits an EM field, the probe assembly 50 moves as needed using linear actuators 310, 315. In one embodiment, the linear actuators 310, 315 are mechanical arms that physically hold the probe assembly 50 in a set position and can be, but are not limited to, moved by pneumatic, electrical, or mechanical means, by stepper motors, or manually by an operator. Linear actuator 310 controls the x-axis movement of the probe assembly 50 by extending towards the antenna under test 312 or retracting away from the antenna under test 312. Linear actuator 315 controls the y-axis movement of the probe assembly 50 by extending or retracting the probe assembly 50 in relation to the antenna under test 312. Both linear actuators 310, 315 move independently of one another to allow precise control of the location of the probe assembly 50 in relation to the antenna under test 312. Further, the rotating table 320 may rotate the antenna under test 312. The EM field measurements collected by probe assembly 50 are analyzed by a network analyzer, spectrum analyzer, oscilloscope or other test equipment. In another EM field mapping scenario, the shield 135 is placed over the tip assembly 100 and the ground wire 140 is attached to earth ground or the reference potential of the test equipment as described herein above. Once the probe assembly 50 is in place, the antenna under test 312 is energized and the probe assembly 50 and rotating table 320 have an arbitrary starting point. As the probe assembly 50 moves or the rotating table 320 rotates, EM field measurements are recorded using the probe assembly 50. To construct an EM field map, the probe assembly 50 is moved using the linear actuators 310, 315 to other sample points corresponding to different r and L values or rotating table 320 is rotated to change 6. EM field measurements are recorded and the values of r, L, and θ are adjusted until a desired EM field mapping is complete. As an example, the probe assembly 50 may be moved in steps in an extended direction or a retracted direction in accordance with the physical size and resolution capability of the head assembly 55. Similarly, each rotation step of table 320 may correspond to the physical size and resolution capability of the head assembly 55. As an example, r and L values may be measured every 1 inch while θ may vary every 5°. At the conclusion of the EM field mapping process, the output will be a collection of 3D EM field measurements all the way around the antenna under test 312. The output may be stored in a measurement log or displayed using a computer monitor.

FIG. 11 displays a 2D rendering of the electromagnetic field 160 of the antenna 38 included with the EM logging tool 36. In FIG. 11, the antenna 38 is mounted at approximately a 45° angle relative to the longitudinal axis of the EM logging tool 36. The electromagnetic field 160 corresponding to the antenna 38 is affected by the characteristics of downhole formations (e.g., formation 19) and can be used to detect formation properties (e.g., resistivity, porosity, density, presence of fluids, boundary detection, geo-steering, etc.) as well as bed boundaries. The accuracy of EM analysis using antenna 38 can be improved by performing EM field mapping for the antenna 38 before its deployment downhole, where the EM field mapping is facilitated using the probe assembly 50 and test stand 328 as described herein.

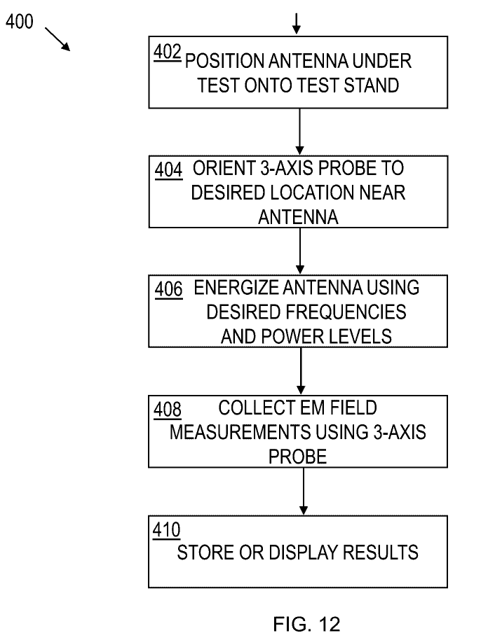

FIG. 12 is a block diagram of a method of performing EM field mapping of an antenna 400. In block 402, the antenna under test is mounted to the rotating table of the test stand, said test stand including a three-axis probe assembly. In block 404, the probe assembly is placed at the desired location within the antenna's EM field by extending/retracting the probe assembly in the x- and y-axis. Manipulation of the probe assembly along the z-axis in the EM field is accomplished by rotating the rotating table. In block 406, the antenna under test is energized at a given power level and frequency. In block 408, measurements are made of the antenna's EM field using the three-axis probe assembly. Different measurements can be made of the EM field by moving either the antenna in relation to the probe assembly or by moving the probe assembly within the EM field. In block 410, the measurement results are recorded in a log or displayed on a computer monitor for further analysis by the operators.

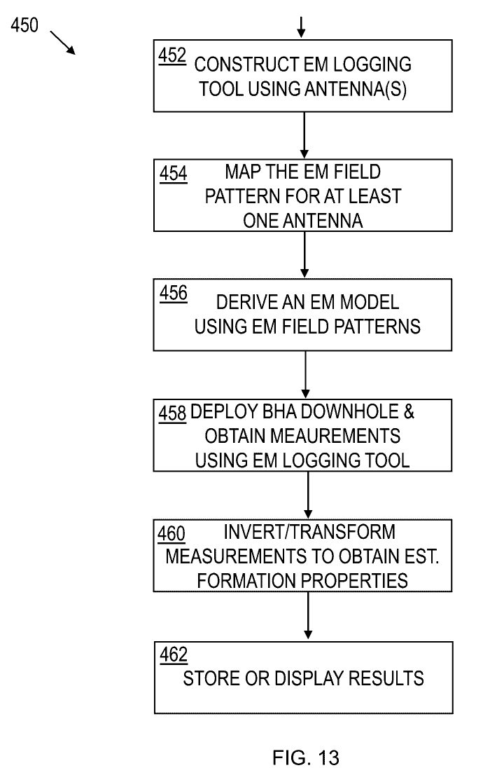

FIG. 13 is a block diagram of performing an EM logging method 450. In block 452, an EM logging tool is constructed to be part of a BHA assembly to be deployed to a predetermined position downhole. The BHA includes at least one antenna. In block 454, the three-axis antenna probe is placed in the test stand and a detailed pattern of the BHA antenna's EM field is measured and recorded. In block 456, based on the measurements made in block 454, an EM model of the antenna is derived and stored. In an alternative embodiment, measurements of the antenna may be used to verify an existing EM model. Other embodiments may include using the measurements to both derive and verify an EM model, or modifying an existing EM model. In block 458, the BHA containing the EM logging tool and antenna is positioned downhole to a predetermined position. The antenna is then energized and the resultant EM measurements are made and recorded. In block 460, the measurements made by the antenna are processed locally, at the surface, or at a remote location by inverting/transforming the measurements to obtain the estimated formation properties. Not all applications require applying an inversion algorithm; less-complicated techniques (e.g. applying a conventional shallow resistivity algorithm) may use simpler transforms to derive the estimated formation properties. In block 462, the results of the analysis are recorded in a log or displayed on a computer monitor for further analysis by the operators. In another embodiment, the operator maps a mockup test antenna that is representative of the antenna to be deployed downhole as part of a BHA. The mockup antenna being tested may represent one, but not all of the antennas being deployed downhole as part of the BHA.

Embodiments disclosed herein include:

A: A probe assembly for performing electromagnetic (EM) field mapping around an antenna, the probe assembly comprising: a probe head base and three coils wrapped around the probe head base and oriented in different directions.

B: A method for performing electromagnetic (EM) field mapping of an antenna, the method comprising: energizing the antenna, and collecting EM field measurements using a three-axis probe at multiple positions relative to the energized antenna.

C: An electromagnetic (EM) field mapping apparatus comprising: a non-metallic/non-magnetic frame; a set of linear motion actuators mounted to the non-metallic frame; a probe assembly coupled to the set of linear motion actuators, wherein the linear motion actuators are controllable to move the probe assembly to each of multiple grid points in a plane; at least one rotatable mounting point on the non-metallic frame that receives a logging while drilling (LWD) or wireline tool having an antenna which generates an EM field, the at least one rotatable mounting point being coupled to a stepper motor to rotate the LWD tool in controlled increments relative to the probe assembly; a sensor coupled to the probe assembly to acquire multicomponent EM field measurements; and a controller coupled to the set of linear motion actuators and the stepper motor to drive the probe assembly to each of the multiple grid points for each rotational orientation of the LWD or wireline tool and to record at least one multicomponent EM field measurement for each combination of grid point and rotational orientation.

D: An electromagnetic EM logging method that comprises: constructing an EM logging tool having one or more antennas; mapping an EM field pattern for at least one of the one or more antennas; deriving an EM logging tool model using the one or more EM field patterns; obtaining measurements using the EM logging tool; and inverting/transforming the measurements using the EM logging tool model to obtain the estimated formation properties.

Each of embodiments A, B, C, and D may have one or more of the following additional elements in any combination: Element 1: further comprising an electrostatic or electric field shield that surrounds the probe head base and the three coils. Element 2: further comprising a capacitor in parallel with each of the three coils to enable frequency tuning Element 3: wherein the probe head base is made from a non-metallic/non-magnetic material. Element 4: wherein the probe head base is made from a metallic or magnetic material. Element 5: further comprising rotating the antenna and collecting EM field measurements using the three-axis probe at multiple rotation angles for the energized antenna. Element 6: wherein energizing the antenna comprising switching between different frequencies. Element 7: wherein energizing the antenna comprising switching between power levels. Element 8: wherein tri-axial coils are incorporated into a probe for mapping of the EM field of an antenna under test. Element 9: wherein multi-frequency measurements are made and recorded using a range of a sinusoidal waveform varying from 10 Hz-10 MHz. Element 10: wherein the composition of the frame is non-metallic or non-magnetic structural materials such as wood, ceramic, glass, polymers including Kevlar, nylon, and Teflon, resin, or composite materials including fiberglass. Element 11: wherein the probe assembly includes interchangeable heads, wherein said heads are constructed to accurately detect field strength in a particular frequency range, including being able to detect signals across a range of 10 Hz to 10 MHz. Element 12: wherein an interchangeable head possesses a diameter from the set including small (less than 0.250 inches in diameter), medium (0.250-1 inch in diameter, and large (greater than 1 inch in diameter). Element 13: wherein a programmable spacing of grid points, corresponding x- and y-axis linear actuator positions and z-axis rotation angles, which corresponds to the size/resolution of a given interchangeable head. Element 14: wherein the control and motion of linear motion actuators includes, but is not limited to pneumatic, electrical, or mechanical means, by stepper motors, or manually by an operator. Element 15: wherein the type of antennas tested include, but are not limited to, co-axial antenna and tilted or angled antennas. Element 16: wherein a power source is included in the apparatus to provide power to drive the antenna under test, said power source having the capability to provide a constant sinusoidal signal or a signal with a varying frequency, which is controlled by a controller. Element 17: wherein claims include: types of formation properties; and details on the mapping operation.

Numerous variations and modifications will become apparent to those skilled in the art once the above disclosure is fully appreciated. It is intended that the following claims be interpreted to embrace all such variations and modifications where applicable.

1. A probe assembly for performing electromagnetic (EM) field mapping around an antenna, the probe assembly comprising:
a probe head base; and
three coils wrapped around the probe head base and oriented in different directions.

2. The probe assembly of claim 1, further comprising an electrostatic or electric field shield that surrounds the probe head base and the three coils.

3. The probe assembly of claim 1, further comprising a capacitor in parallel with each of the three coils to enable frequency tuning.

4. The probe assembly of claim 1, wherein the probe head base is made from a non-metallic/non-magnetic material.

5. The probe assembly of claim 1, wherein the probe head base is made from a metallic or magnetic material.

6. A method for performing electromagnetic (EM) field mapping of an antenna, the method comprising:
energizing the antenna; and
collecting EM field measurements using a three-axis probe at multiple positions relative to the energized antenna.

7. The method of claim 6, further comprising rotating the antenna and collecting EM field measurements using the three-axis probe at multiple rotation angles for the energized antenna.

8. The method of claim 6, wherein energizing the antenna comprising switching between different frequencies.

9. The method of claim 6, wherein energizing the antenna comprising switching between power levels.

10. An electromagnetic (EM) field mapping apparatus comprising:
a non-metallic/non-magnetic frame;
a set of linear motion actuators mounted to the non-metallic frame;
a probe assembly coupled to the set of linear motion actuators, wherein the linear motion actuators are controllable to move the probe assembly to each of multiple grid points in a plane;
at least one rotatable mounting point on the non-metallic frame that receives a logging while drilling (LWD) or wireline tool having an antenna which generates an EM field, the at least one rotatable mounting point being coupled to a stepper motor to rotate the LWD tool in controlled increments relative to the probe assembly;
a sensor coupled to the probe assembly to acquire multicomponent EM field measurements; and
a controller coupled to the set of linear motion actuators and the stepper motor to drive the probe assembly to each of the multiple grid points for each rotational orientation of the LWD or wireline tool and to record at least one multicomponent EM field measurement for each combination of grid point and rotational orientation.

11. The EM field mapping apparatus of claim 10, wherein tri-axial coils are incorporated into a probe for mapping of the EM field of an antenna under test.

12. The EM field mapping apparatus of claim 10, wherein multi-frequency measurements are made and recorded using a range of a sinusoidal waveform varying from 10 Hz-10 MHz.

13. The EM field mapping apparatus of claim 10, wherein the composition of the frame is non-metallic or non-magnetic structural materials such as wood, ceramic, glass, polymers including Kevlar, nylon, and Teflon, resin, or composite materials including fiberglass.

14. The EM field mapping apparatus of claim 10, wherein the probe assembly includes interchangeable heads, wherein said heads are constructed to accurately detect field strength in a particular frequency range, including being able to detect signals across a range of 10 Hz to 10 MHz.

15. The EM field mapping apparatus of claim 10, wherein an interchangeable head possesses a diameter from the set including small (less than 0.250 inches in diameter), medium (0.250-1 inch in diameter, and large (greater than 1 inch in diameter).

16. The EM field mapping apparatus of claim 10, wherein a programmable spacing of grid points, corresponding x- and y-axis linear actuator positions and z-axis rotation angles, which corresponds to the size/resolution of a given interchangeable head.

17. The EM field mapping apparatus of claim 10, wherein the control and motion of linear motion actuators includes, but is not limited to pneumatic, electrical, or mechanical means, by stepper motors, or manually by an operator.

18. The EM field mapping apparatus claim 10, wherein the type of antennas tested include, but are not limited to, co-axial antenna and tilted or angled antennas.

19. The EM field mapping apparatus of claim 10, wherein a power source is included in the apparatus to provide power to drive the antenna under test, said power source having the capability to provide a constant sinusoidal signal or a signal with a varying frequency, which is controlled by a controller.

20. An electromagnetic EM logging method that comprises:
constructing an EM logging tool having one or more antennas;
mapping an EM field pattern for at least one of the one or more antennas;
deriving an EM logging tool model using the one or more EM field patterns;
obtaining measurements using the EM logging tool; and
inverting/transforming the measurements using the EM logging tool model to obtain the estimated formation properties.

21. The EM logging method of claim 20, wherein claims include:
types of formation properties; and
details on the mapping operation.
